(19) United States
(12) Patent Application Publication
(10) Pub. No.: US 2025/0372947 A1
(43) Pub. Date: Dec. 4, 2025

(54) SYSTEMS AND METHOD FOR PHASE LOCKING AN ARRAY OF LASERS

(71) Applicant: THE MITRE CORPORATION, McLean, VA (US)

(72) Inventors: Robert C. HOUVENER, Hollis, NH (US); Michael STENNER, Vienna, VA (US); Rory LAMOND, Washington, DC (US); Aliaksandr A. MAMONAU, Bethesda, MD (US); Gregory Frank CARDINALE, Duxbury, MA (US); Chenglong ZHAO, Falls Church, VA (US)

(73) Assignee: THE MITRE CORPORATION, McLean, VA (US)

(21) Appl. No.: 19/226,417

(22) Filed: Jun. 3, 2025

Related U.S. Application Data
(60) Provisional application No. 63/655,394, filed on Jun. 3, 2024.

(51) Int. Cl. H01S 5/065; H01S 5/02253; H01S 5/42

(52) U.S. Cl. CPC H01S 5/0657; H01S 5/02253; H01S 5/423

(57) ABSTRACT

A hybrid transmit and receive array is provided. The hybrid transmit and receive array can include an array of microlenses positioned at a distance d from an array of lasers, the array of microlenses having one element for each laser in the array of lasers. The hybrid transmit and receive array can include a plurality of diffractive optical elements positioned at the distance d from the array of microlenses, each diffractive optical element positioned in overlap regions of the lasers in the array of lasers, each diffractive optical element causing at least some of the light in respective the overlap region to reflect back into its neighbors to cause self-locking of the array of lasers.

### CROSS REFERENCE TO RELATED APPLICATIONS

This application claims priority to and the benefit of U.S. Provisional Patent Application No. 63/655,394, filed on Jun. 3, 2024, the entire contents of which are owned by the assignee of the instant application and incorporated herein by reference in its entirety.

### FIELD OF THE INVENTION

The invention relates generally to micro-laser arrays. In particular, systems and methods for causing micro-laser arrays to be efficient and coherent.

### BACKGROUND

Micro-laser arrays can be devices consisting of many small lasers arranged in a grid or pattern, typically on a chip-scale surface.

In order for an array of lasers to propagate and focus efficiently as a single laser or composite, single laser, coherency (or substantial coherency) can be desired, e.g., the emission can have a common electromagnetic phase. Typical current methods for achieving coherence can include independent phase control of each laser to the same phase and/or down-stream measurement to provide feedback to that control; using a “seed” laser to inject into another laser to set the phase for all lasers in the array; and/or “self-locking” by sharing light between lasers in the array. Typical current methods can require additional expensive device elements and can require precise alignment of optical components.

Therefore, it can be desirable to have a less expensive, more compact coherent array of lasers.

### SUMMARY OF THE INVENTION

In one aspect, the invention includes a hybrid transmit and receive array. The hybrid transmit and receive array includes an array of microlenses positioned at a distance d from an array of lasers, the array of microlenses having one element for each laser in the array of lasers, and a plurality of diffractive optical elements positioned at the distance d from the array of microlenses, each diffractive optical element positioned in overlap regions of the lasers in the array of lasers, each diffractive optical element causing at least some of the light in respective the overlap region to reflect back into its neighbors to cause self-locking of the array of lasers.

In some embodiments, the microlenses and diffractive optical elements are fabricated on one substrate. In some embodiments, the plurality of diffractive optical elements are micromirrors, microgratings, or Fresnel lens.

In some embodiments, each laser in the array of lasers is a vertical cavity surface emitting laser (VCSEL), a fiber laser or a semiconductor laser. In some embodiments, a number of lasers in the array of lasers is between 2 and 1,000,000. In some embodiments, the number of plurality of diffractive optical elements is two, three or four.

In another aspect, the invention includes a microlens. The microlens includes a main lens portion for collimating received light, and a plurality of diffractive optical elements positioned on the main lens to reflect at least a portion of the received light back.

In some embodiments, the number of plurality of diffractive optical elements is two, three or four. In some embodiments, the plurality of diffractive optical elements are micromirrors.

### BRIEF DESCRIPTION OF THE DRAWINGS

Non-limiting examples of embodiments of the disclosure are described below with reference to figures attached hereto that are listed following this paragraph. Dimensions of features shown in the figures are chosen for convenience and clarity of presentation and are not necessarily shown to scale.

The subject matter regarded as the invention is particularly pointed out and distinctly claimed in the concluding portion of the specification. The invention, however, both as to organization and method of operation, together with objects, features and advantages thereof, can be understood by reference to the following detailed description when read with the accompanied drawings. Embodiments of the invention are illustrated by way of example and not limitation in the figures of the accompanying drawings, in which like reference numerals indicate corresponding, analogous or similar elements, and in which:

FIG. 1 is an example showing a three-dimensional view and top down view of a phase locking laser array, according to some embodiments of the invention.

FIG. 2 is an example showing a three-dimensional view and top down view of a portion of a phase locking laser array, according to some embodiments of the invention.

FIG. 3 shows a diagram of a three dimensional image of a microlens, according to some embodiments of the invention.

FIG. 4 is a schematic diagram of a portion of phase locking laser array 400, according to some embodiments of the invention.

FIG. 5 are graphs showing example output of the hybrid transmit and receive antenna, according to some embodiments of the invention.

FIG. 6 are plots showing example output, according to some embodiments of the invention.

FIG. 7 is a system architecture of a system that incorporates a phase locking antenna array, according to some embodiments.

It will be appreciated that for simplicity and clarity of illustration, elements shown in the figures have not necessarily been drawn accurately or to scale. For example, the dimensions of some of the elements can be exaggerated relative to other elements for clarity, or several physical components can be included in one functional block or element.

### DETAILED DESCRIPTION

In the following detailed description, numerous specific details are set forth in order to provide a thorough understanding of the invention. However, it will be understood by those skilled in the art that the invention can be practiced without these specific details. In other instances, well-known methods, procedures, and components, modules, units and/or circuits have not been described in detail so as not to obscure the invention.

Generally, the invention involves a new, compact, and/or efficient system and method to share light between lasers and achieve self-locking.

Typically, without any optics in front of a laser array the individual lasers output each diverge and overlap. For example, the electromagnetic energy exiting each laser (e.g., a laser beam) can intersect with electromagnetic energy from other lasers, for example, its respective neighbor lasers. The region where this occurs can be referred to as an overlap region.

A hybrid receive and transmit array (HRTA) can be positioned after an array of lasers to collimate the individual laser beams. The HRTA can include a microlens array with a reflective surface. The HRTA can receive the laser beams from each of the lasers in the laser array before a substantial divergence of the laser beams occurs, and can collimate the laser beams. There is still typically some (e.g., 1.0-100 milli radians) laser beam divergence (e.g., divergence is inversely proportional to the beam size) and overlap prior to the laser beam impinging upon the HRTA, thus some laser beam losses can occur. A HRTA can be positioned at a distance with respect to the laser array such that that the individual laser beams do not overlap or overlap very little.

In some embodiments of the invention, in order to cause phase locking, the HRTA can be positioned with respect to the laser array such that the beams can over overlap slightly (e.g., with ˜1% of the light from each beam overlapping its neighbors) and the HRTA can be physically modified to direct the beam (e.g., light) in the overlap region from each laser back into its neighbor lasers. Directing the light into the neighbor lasers for all lasers in a laser array can cause small groups of the lasers to become phase locked, and the small groups can cause other small groups to be phased locked, and so on until the entire laser array has substantially one phase.

The microlens of the HRTA can be modified in multiple ways to direct light back from its associated laser into the neighbor of the said laser. In various embodiments, the microlens can include a mirror such that it reflects a portion of the beam back into its neighbor, or the microlens can be a diffractive optical element (DOE) to behave as a diffraction grating and diffract light from each laser into its neighbor.

In order to, for example, operate efficiently, the HRTA can a) use only as much light reflected back into the neighbor as is required to achieve the self-locking, allowing the majority of light to be collimated by the HRTA, and/or b) direct the reflected back light into the neighbor lasers in a way that strongly overlaps the neighbor laser's spatial mode, ensuring that the light can be coupled into the laser and achieve the desired locking effect.

Embodiments of the invention use of the overlap region to transfer light between neighboring lasers.

Reflecting light back into the neighbors can be used with any laser array, and can avoid modification of the laser array itself.

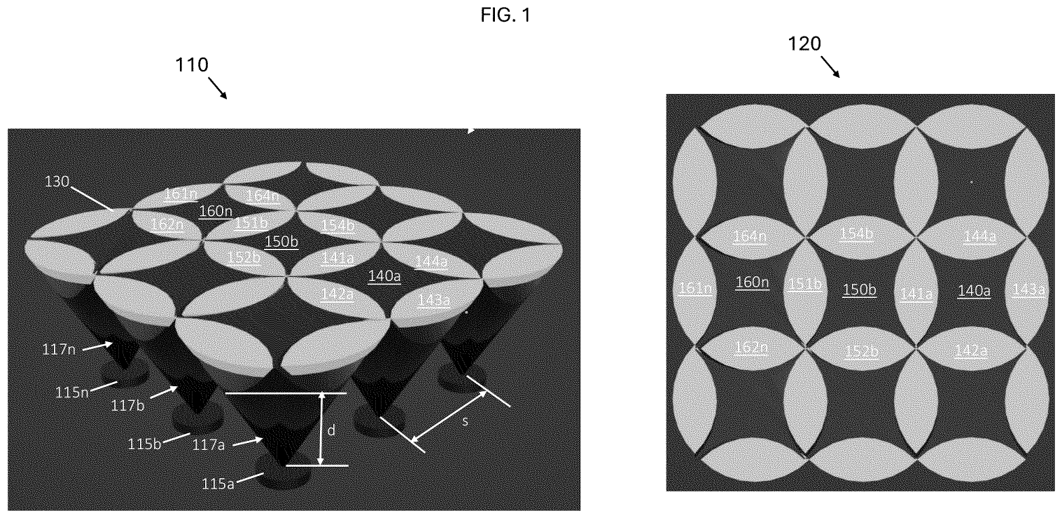

FIG. 1 is an example showing a three-dimensional view 110 and top down view 120 of a phase locking laser array, according to some embodiments of the invention. There are a plurality of individual laser emitters, 115a, 115b, . . . , 115n, generally laser emitters 115. Each emitter emitting a respective laser beam, 117a, 117b, . . . , 117n, generally laser beam 117.

The phase locking laser arrays can have individual laser emitters 115 that are positioned at the same spacing throughout, and having the same aperture. A HRTA 130 can be positioned at a distance d from the individual laser emitters 115. The relationship among the distance d, the aperture of the laser emitters D 115 and/or a spacing s (P) between the laser emitters can be as shown below in EQN. 1:

$$d = 0 \text{.5} P / tan ( arc sin ( 1.22 λ ) / D ) \qquad EQN . 1$$

where λ is the wavelength of the laser 115. In some embodiments of the invention the distance d can be on the order of 1 to 10 millimeters. The distance d can be such that that the HRTA 130 where the respective laser beams 117 from each laser emitter 115 do not overlap or overlap very little.

The HRTA 130 can have multiple portions. Each portion can be dedicated to collimated/reflecting the respective laser beams 117 of the laser emitter 115. Each portion can include a microlens, a plurality of micromirrors and/or a plurality of diffractive optical elements to cause a portion of the respective laser beams 117 emitting from its corresponding individual laser emitter 115 to be reflected back into its neighbors (e.g., the portion of the beam in the overlap region) and a portion of the beam to be collimated.

For example, a first portion of the multiple portions can include a region without overlap between the laser beam beams 140a and overlap regions 141a, 142a, 143a, and 144a. A second portion can include a region without overlap between the laser beam beams 150b and overlap regions 141a, 152b, 153b, and 154b. A third portion can include a region without overlap between the laser beam beams 160n and overlap regions 161n, 162n, 151b, and 164n.

In some embodiments, the HRTA 130 include a plurality of microlenses and the micromirrors (or diffractive optical elements) are positioned side by side, e.g., microlenses are located within portion 140a, 150b, 160n to collimate the beam.

In various embodiments, the micromirrors are circular, oval, square, rectangular, or triangular shaped. The size and/or shape of each micromirrors/diffractive optical element can vary. The thickness of the micromirrors/diffractive optical element can vary. The shape and/or thickness can vary in the same device, such that the micromirrors/diffractive optical element are non-uniform. The size and/or shape of each micromirrors/diffractive optical element can be based on a desired percentage of the beam to be reflected back into the neighbor(s), a shape of the portion of the HRTA 130, power in the laser beam 117, size of the overlap region, the distance of the HRTA 130 from the laser emitters 115 or any combination thereof.

In some embodiments, the HRTA 130 has micromirror/diffractive optical elements positioned/size such that each laser emitter 115 reflects into each of its neighbors. In various embodiments, the HRTA 130 has micromirror/diffractive optical elements positioned/size such that each laser emitter 117 reflects into any predetermined number of the neighbors.

As is obvious to one of ordinary skill in the art, the number laser emitters 115 and the number of elements in the HRTA 130 shown in FIG. 1 is for example purposes only. In various embodiments, the number of laser emitters 115 and the number of HRTA 130 can be on the order of thousands of emitters. In some embodiments in which the laser emitters 115 are lithographically patterned semiconductor lasers, the total number of possible laser emitters 115 in the HRTA 130 can be determined as shown below in EQN. 2:

$$N = π ( 0.5 WS * WS ) / ( P * P ) \qquad EQN . 2$$

where WS is wafer size and P is laser distance.

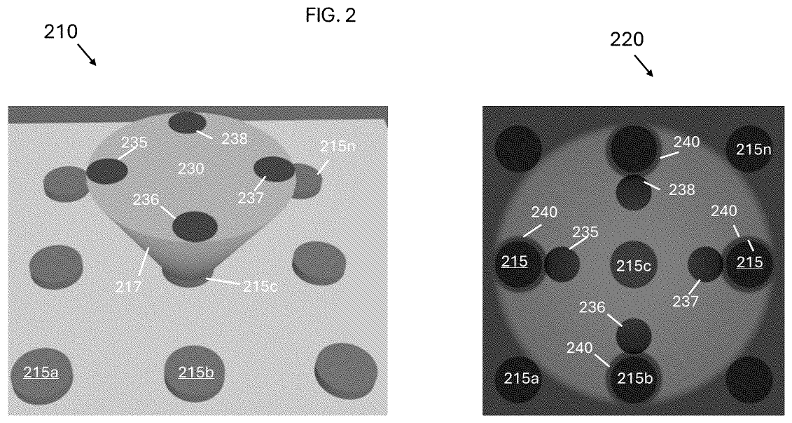

FIG. 2 is an example showing a three-dimensional view 210 and top down view 220 of a portion of a phase locking laser array, according to some embodiments of the invention. The three-dimensional view 110 shows an array of vertical cavity surface emitting lasers (VCSELs) 215a, 215b, 215c, . . . 215n, generally 215, with a laser beam 217 emitting from one VSCEL 215c, and one HRTA element 230. The one HRTA element 230 can be at a distance of d from the VCSEL, as described above. The HRTA element 230 can be repeated for each VCSEL. Each element in the HRTA can include four micromirrors where each element in the HRTA can share a micromirror with a neighbor wherever a neighbor exists,

The top down view 220 shows a portion 240 of the laser beam 217 from the VCSEL 215c can be reflected to each neighbor, 215.

Table 1 shown below is example dimensions for elements of a phase locking laser array of FIG. 2, according to some embodiments.

TABLE 1

| VCSEL | VCSEL | Mirror | Laser | Mirror | | |
|---|---|---|---|---|---|---|
| Diameter | Pitch | Height | Spot | Diameter | Seeding | Trans- |
| (μm) | (μm) | (μm) | (μm) | (μm) | Efficiency | mission |
| 5 | 15 | 35 | 20 | 2.8 | 2.0% | 92% |
| 10 | 30 | 144 | 40 | 5.7 | 2.0% | 92% |

The seeding efficiency can be an amount of the laser beam (e.g., light) from each VCSEL that is directed to each of its neighbors. In the example of FIG. 2 as shown above in Table 1, a seeding efficiency of 2% can yield 8% of the laser beam being reflected back. The percentage can be determined as shown below in EQN. 3:

$$Seeding efficiency = {( \frac{0.5 \times D}{P + 0.5 D} )}^{2} \qquad EQN . 3$$

where D is aperture of the laser element and p is distance between nearby lasers. In the example of FIG. 1, applying EQN. 1 yields, 2%*4VCELS=8%, meaning the unimpeded laser beam from each laser, 92% of the laser beam is transmitted and 8% is reflected back to the neighbors. The seeding efficiency can depend on the aperture of the laser element D and the distance between nearby lasers p.

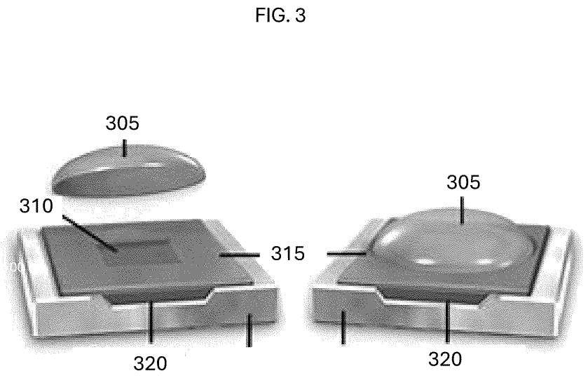

FIG. 3 shows a diagram of a three dimensional image of a microlens (e.g., Lenslet) 300, according to some embodiments of the invention. The microlens 300 includes an optical lens 305 positioned over a dye layer 310 and metal light shield 315 of a photodiode 320. The microlens 300 can be constructed according to manufacturing techniques as are known in the art. The micromirrors (or diffractive optical elements) can be positioned side by side with the microlens 300. For example, microlens 305 can be placed within the portion 140a, 150b, and 160n. The microlens and the micromirrors can be fabricated on the same substrate and combined into one hybrid element.

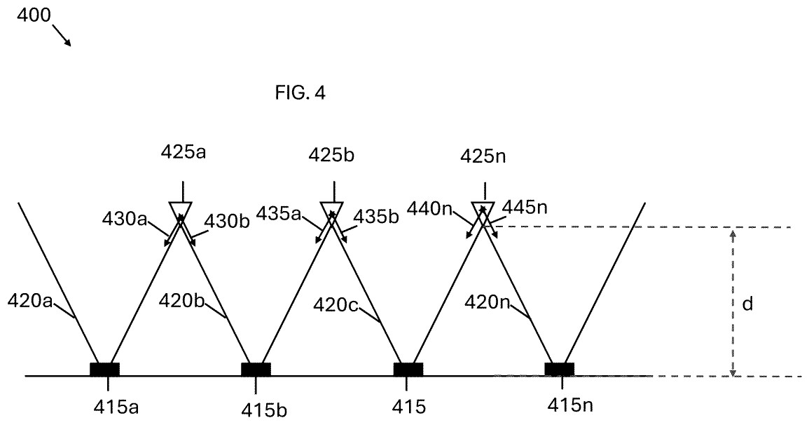

FIG. 4 is a schematic diagram of a portion of phase locking laser array 400, according to some embodiments of the invention. The phase locking laser array includes a plurality of VCSELs, 415a, 415b, 415c, . . . 415n, generally 415, each having a laser beam 420a, 420b, 420c, . . . 420n, generally 420. A microlens (not shown) can positioned at a distance d from the VCSELs. The phase locking laser array 400 can have a plurality of micromirrors 425a, 425b, 425n, generally 425, which reflect a portion of the laser beam 420 (e.g., light) back to a neighbor. The reflected beams 430, 430b, 435a, 435b, 400n, and 445n, can travel back into the VCSELs to cause the phase of each VCSEL emission to synchronize. In this manner, the laser array can become self locking in phase.

The plurality of micromirrors 425 can be positioned in a region where the laser beam emission from each of the VCSELs overlap.

In various embodiments, each microlens has a number of micromirrors (or diffractive optical elements) equal to a number of nearest neighbors. In various embodiments, each microlens has a number of micromirrors (or diffractive optical elements) of one, two, three, four, or five.

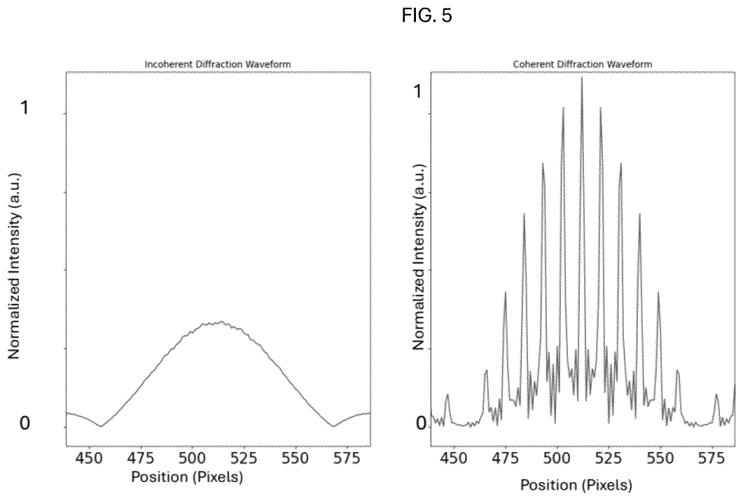

FIG. 5 are graphs showing example output of the hybrid transmit and receive antenna, according to some embodiments of the invention. The y-axis is power (e.g., in milliwatts) and the x-axis is distance (e.g., in millimeters) from the phase locking laser array. The incoherent diffraction waveform shows an example of the output when there is no reflection of a portion of the beam into the nearest neighbor, thus no phase locking. The coherent diffraction waveform shows a much higher power response when there is a reflection of a portion of the beam into the nearest neighbor to cause phase locking.

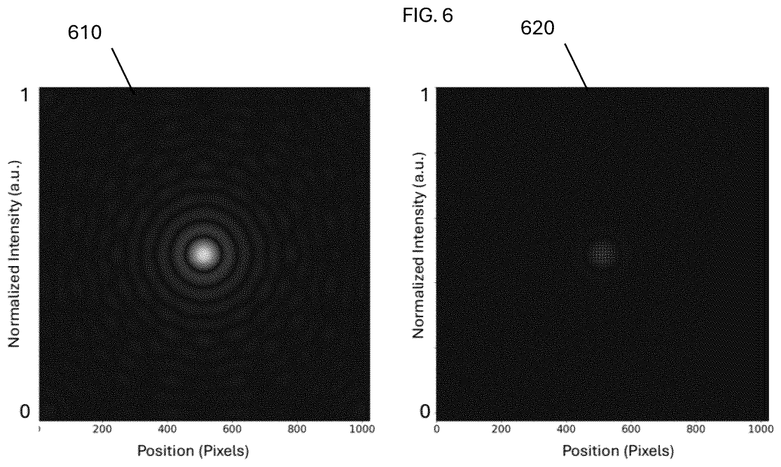

FIG. 6 are plots showing example output, according to some embodiments of the invention. The y-axis is power (e.g., in milliwatts) and the x-axis is distance (e.g., in millimeters) from a phase locking laser array (e.g., the phase locking laser array as shown above in FIG. 6). The incoherent diffraction waveform 610 shows an example of the output when there is no reflection of a portion of the beam into the nearest, thus no phase locking. The coherent diffraction waveform 620 shows a much higher power response when there is a reflection of a portion of the beam into the nearest neighbor to cause phase locking.

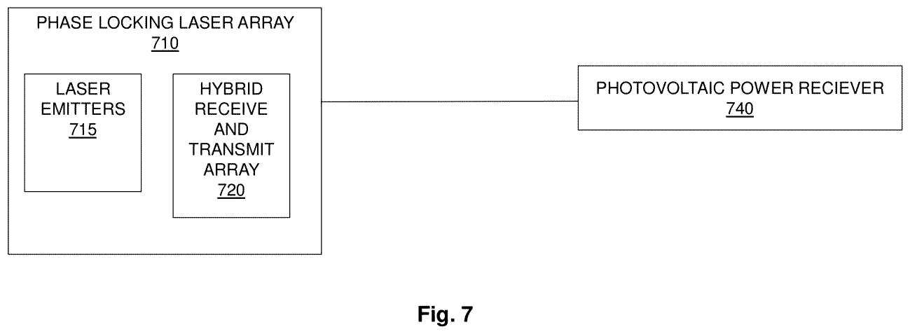

FIG. 7 is a system architecture of a system that incorporates a phase locking antenna array, according to some embodiments. The system can include a phase locking antenna array 710 and a photovoltaic power receiver 740. The phase locking antenna array 710 can include a plurality of laser emitters 715 and a hybrid receive and transmit array 720 (e.g., the hybrid receive and transmit array as described above in FIG. 1). The phase locking antenna array 710 can be the phase locking antenna array of FIG. 1.

The phase locking antenna array 710 can transmit a coherent laser beam (e.g., beam 620 as shown above in FIG. 6) to the photovoltaic power receiver 740. Due to the coherent laser beam, the power received by the photovoltaic power receiver 740 can be greater compared to an incoherent laser beam (e.g., beam 610 as shown above in FIG. 6).

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

Before at least one embodiment of the invention is explained in detail, it is to be understood that the invention is not limited in its application to the details of construction and the arrangement of the components set forth in the following description or illustrated in the drawings. The invention is applicable to other embodiments that may be practiced or carried out in various ways as well as to combinations of the disclosed embodiments. Also, it is to be understood that the phraseology and terminology employed herein is for the purpose of description and should not be regarded as limiting.

Unless specifically stated otherwise, as apparent from the following discussions, it is appreciated that throughout the specification discussions utilizing terms such as “processing”, “computing”, “calculating”, “determining”, “enhancing” or the like, refer to the action and/or processes of a computer or computing system, or similar electronic computing device, that manipulates and/or transforms data represented as physical, such as electronic, quantities within the computing system's registers and/or memories into other data similarly represented as physical quantities within the computing system's memories, registers or other such information storage, transmission or display devices. Any of the disclosed modules or units may be at least partially implemented by a computer processor.

As used herein, “machine learning”, “machine learning algorithms”, “machine learning models”, “ML”, or similar, may refer to models built by algorithms in response to/based on input sample or training data. ML models may make predictions or decisions without being explicitly programmed to do so. ML models require training/learning based on the input data, which may take various forms.

As will be appreciated by one skilled in the art, aspects of the present invention may be embodied as a system or an apparatus. Accordingly, aspects of the present invention may take the form of an entirely hardware embodiment or an embodiment combining software and hardware aspects that may all generally be referred to herein as a “circuit,” “module” or “system.”

The aforementioned figures illustrate the architecture, functionality, and operation of possible implementations of systems and apparatus according to various embodiments of the present invention. Where referred to in the above description, an embodiment is an example or implementation of the invention. The various appearances of “one embodiment,” “an embodiment” or “some embodiments” do not necessarily all refer to the same embodiments.

Although various features of the invention may be described in the context of a single embodiment, the features may also be provided separately or in any suitable combination. Conversely, although the invention may be described herein in the context of separate embodiments for clarity, the invention may also be implemented in a single embodiment.

Reference in the specification to “some embodiments”, “an embodiment”, “one embodiment” or “other embodiments” means that a particular feature, structure, or characteristic described in connection with the embodiments is included in at least some embodiments, but not necessarily all embodiments, of the inventions. It will further be recognized that the aspects of the invention described hereinabove may be combined or otherwise coexist in embodiments of the invention.

It is to be understood that the phraseology and terminology employed herein is not to be construed as limiting and are for descriptive purpose only.

The principles and uses of the teachings of the present invention may be better understood with reference to the accompanying description, figures and examples.

It is to be understood that the details set forth herein do not construe a limitation to an application of the invention.

Furthermore, it is to be understood that the invention can be carried out or practiced in various ways and that the invention can be implemented in embodiments other than the ones outlined in the description above.

It is to be understood that the terms “including”, “comprising”, “consisting” and grammatical variants thereof do not preclude the addition of one or more components, features, steps, or integers or groups thereof and that the terms are to be construed as specifying components, features, steps or integers.

If the specification or claims refer to “an additional” element, that does not preclude there being more than one of the additional element.

It is to be understood that where the claims or specification refer to “a” or “an” element, such reference is not be construed that there is only one of that element.

It is to be understood that where the specification states that a component, feature, structure, or characteristic “may”, “might”, “can” or “could” be included, that particular component, feature, structure, or characteristic is not required to be included.

Where applicable, although state diagrams, flow diagrams or both may be used to describe embodiments, the invention is not limited to those diagrams or to the corresponding descriptions. For example, flow need not move through each illustrated box or state, or in exactly the same order as illustrated and described.

Methods of the present invention may be implemented by performing or completing manually, automatically, or a combination thereof, selected steps or tasks.

The term “method” may refer to manners, means, techniques and procedures for accomplishing a given task including, but not limited to, those manners, means, techniques and procedures either known to, or readily developed from known manners, means, techniques and procedures by practitioners of the art to which the invention belongs.

The descriptions, examples and materials presented in the claims and the specification are not to be construed as limiting but rather as illustrative only.

Meanings of technical and scientific terms used herein are to be commonly understood as by one of ordinary skill in the art to which the invention belongs, unless otherwise defined.

The present invention may be implemented in the testing or practice with materials equivalent or similar to those described herein.

While the invention has been described with respect to a limited number of embodiments, these should not be construed as limitations on the scope of the invention, but rather as exemplifications of some of the preferred embodiments. Other or equivalent variations, modifications, and applications are also within the scope of the invention. Accordingly, the scope of the invention should not be limited by what has thus far been described, but by the appended claims and their legal equivalents.

What is claimed is:

1. A hybrid transmit and receive array, the hybrid transmit and receive array comprising:
an array of microlenses positioned at a distance d from an array of lasers, the array of microlenses having one element for each laser in the array of lasers; and
a plurality of diffractive optical elements positioned at the distance d from the array of microlenses, each diffractive optical element positioned in overlap regions of the lasers in the array of lasers, each diffractive optical element causing at least some of the light in respective the overlap region to reflect back into its neighbors to cause self-locking of the array of lasers.

2. The hybrid transmit and receive array of claim 1 wherein the microlenses and diffractive optical elements are fabricated on one substrate.

3. The hybrid transmit and receive array of claim 1 wherein the plurality of diffractive optical elements are micromirrors, microgratings, or Fresnel lens.

4. The hybrid transmit and receive array of claim 1 wherein each laser in the array of lasers is a vertical cavity surface emitting laser (VCSEL), a fiber laser or a semiconductor laser.

5. The hybrid receive and transmit laser array of claim 1 where a number of lasers in the array of lasers is between 2 and 1,000,000.

6. The microlens of claim 1 wherein the number of plurality of diffractive optical elements is two, three or four.

7. A microlens, the microlens comprising:
a main lens portion for collimating received light; and
a plurality of diffractive optical elements positioned on the main lens to reflect at least a portion of the received light back.

8. The microlens of claim 6 wherein the number of plurality of diffractive optical elements is two, three or four.

9. The microlens of claim 6 wherein the plurality of diffractive optical elements are micromirrors.
